(19) United States
(12) Patent Application Publication
(10) Pub. No.: US 2025/0201531 A1
(43) Pub. Date: Jun. 19, 2025

(54) HEATING DEVICE AND SUBSTRATE TREATING APPARATUS INCLUDING THE SAME

(71) Applicant: SEMES CO., LTD., Cheonan-si (KR)

(72) Inventors: Chan Young CHOI, Gyeonggi-do (KR); Sun Wook JUNG, Gyeonggi-do (KR); In Ho KIM, Daegu (KR); Cheng Bin CUI, Gyeonggi-do (KR); Hyung Bin IM, Seoul (KR)

(73) Assignee: SEMES CO., LTD., Cheonan-si (KR)

(21) Appl. No.: 18/941,284

(22) Filed: Nov. 8, 2024

(30) Foreign Application Priority Data
Dec. 14, 2023 (KR) 10-2023-0181544

(51) Int. Cl. H01J 37/32; H05B 1/02; H05B 6/68

(52) U.S. Cl. CPC H01J 37/32522; H01J 37/32715; H05B 1/0233; H05B 6/68; H01J 2237/20214; H01J 2237/24585

(57) ABSTRACT

A heating device capable of uniformly maintaining a surface temperature of each zone of a substrate and a substrate treating apparatus including the same are provided. The substrate treating apparatus comprises a chamber housing providing a space in which a substrate is treated; a substrate support unit supporting the substrate inside the chamber housing; a showerhead unit providing a process gas into the chamber housing; a plasma generating unit generating plasma for treating the substrate inside the chamber housing by using the process gas; and a heating device heating the substrate by using a plurality of electromagnetic waves, wherein the plurality of electromagnetic waves are different from each other in at least one component of power, frequency or phase.

### CROSS-REFERENCE TO RELATED APPLICATION

This application claims priority from Korean Patent Application No. 10-2023-0181544 filed on Dec. 14, 2023 in the Korean Intellectual Property Office and all the benefits accruing therefrom under 35 U.S.C. 119, the contents of which in its entirety are herein incorporated by reference.

### BACKGROUND

### Technical Field

The present disclosure relates to a heating device applied to an apparatus for treating a substrate by using plasma. Also, the present disclosure relates to a substrate treating apparatus including the heating device and a semiconductor manufacturing facility including the substrate treating apparatus.

### Description of the Related Art

When a substrate is treated using plasma, an antenna module may be disposed on an upper portion of the substrate, and the antenna module may be used as an electrode. However, while the substrate is being treated, intensity of an electromagnetic field in a chamber may become unstable due to a standing wave effect or the like, and in this case, a surface temperature of each zone of the substrate may become uneven.

### BRIEF SUMMARY

An object of the present disclosure is to provide a heating device capable of uniformly maintaining a surface temperature of each zone of a substrate and a substrate treating apparatus including the same.

The objects of the present disclosure are not limited to those mentioned above and additional objects of the present disclosure, which are not mentioned herein, will be clearly understood by those skilled in the art from the following description of the present disclosure.

A substrate treating apparatus according to one aspect of the present disclosure devised to achieve the above objects comprises a chamber housing providing a space in which a substrate is treated; a substrate support unit supporting the substrate inside the chamber housing; a showerhead unit providing a process gas into the chamber housing; a plasma generating unit generating plasma for treating the substrate inside the chamber housing by using the process gas; and a heating device heating the substrate by using a plurality of electromagnetic waves, wherein the plurality of electromagnetic waves are different from each other in at least one component of power, frequency or phase.

A heating device according to one aspect of the present disclosure devised to achieve the above objects comprises a plurality of microwave generating modules generating a plurality of microwaves; a waveguide guiding the plurality of microwaves to a space in which the substrate is treated; and a control module controlling an operation of each microwave generating module, wherein the substrate is heated using the plurality of microwaves by an apparatus for treating the substrate by using plasma, and the plurality of microwaves are different from each other in at least one component of power, frequency or phase.

A substrate treating apparatus according to another aspect of the present disclosure devised to achieve the above objects comprises a chamber housing providing a space in which a substrate is treated; a substrate support unit supporting the substrate inside the chamber housing; a showerhead unit providing a process gas into the chamber housing; a plasma generating unit generating plasma for treating the substrate inside the chamber housing by using the process gas; and a heating device heating the substrate by using a plurality of electromagnetic waves, wherein the heating device includes: a plurality of microwave generating modules generating the plurality of microwaves; a waveguide guiding the plurality of microwaves to the space in which the substrate is treated; a temperature measurement module including a plurality of temperature sensors and measuring a surface temperature of each zone of the substrate; and a control module controlling an operation of each microwave generating module and each temperature sensor, wherein the plurality of microwaves are different from each other in at least one component of power, frequency or phase, and the control module heats the substrate while the substrate is being treated, and selectively heats the substrate based on the surface temperature of each zone of the substrate.

Details of the other embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a first exemplary view schematically illustrating an internal structure of a semiconductor manufacturing facility for treating a substrate;

FIG. 2 is a second exemplary view schematically illustrating an internal structure of a semiconductor manufacturing facility for treating a substrate;

FIG. 3 is a third exemplary view schematically illustrating an internal structure of a semiconductor manufacturing facility for treating a substrate;

FIG. 4 is a first exemplary view illustrating an internal structure of a substrate treating apparatus constituting a semiconductor manufacturing facility in a cross-sectional view;

FIG. 5 is a second exemplary view illustrating an internal structure of a substrate treating apparatus constituting a semiconductor manufacturing facility in a cross-sectional view;

FIG. 6 is a third exemplary view illustrating an internal structure of a substrate treating apparatus constituting a semiconductor manufacturing facility in a cross-sectional view;

FIG. 7 is a first exemplary view schematically illustrating an internal configuration of a heating device constituting a substrate treating apparatus;

FIG. 8 is a first exemplary view illustrating an embodiment of a waveguide constituting a heating device;

FIG. 9 is a second exemplary view illustrating an embodiment of a waveguide constituting a heating device;

FIG. 10 is a third exemplary view illustrating an embodiment of a waveguide constituting a heating device;

FIG. 11 is a fourth exemplary view illustrating an embodiment of a waveguide constituting a heating device;

FIG. 12 is a fifth exemplary view illustrating an embodiment of a waveguide constituting a heating device;

FIG. 13 is a sixth exemplary view illustrating an embodiment of a waveguide constituting a heating device;

FIG. 14 is a flow chart illustrating a substrate heating method when a substrate is treated in accordance with one embodiment;

FIG. 15 is a flow chart illustrating a substrate heating method when a substrate is treated in accordance with another embodiment;

FIG. 16 is a second exemplary view schematically illustrating an internal configuration of a heating device constituting a substrate treating apparatus;

FIG. 17 is a first exemplary view illustrating an embodiment of a temperature measurement module constituting a heating device;

FIG. 18 is a second exemplary view illustrating an embodiment of a temperature measurement module constituting a heating device; and

FIG. 19 is an exemplary view illustrating a method of rotating a substrate.

### DETAILED DESCRIPTION OF THE DISCLOSURE

Hereinafter, the embodiment of the present disclosure will be described in detail with reference to the accompanying drawings. The same reference numerals will be used for the same elements on the drawings, and their redundant description will be omitted.

A heating device may be applied to a substrate treating apparatus by using plasma. The heating device may uniformly maintain an internal temperature of a process chamber while a substrate treating process is being performed, and may shorten the time required to complete the substrate treating process. The heating device may uniformly maintain a surface temperature of each zone of the substrate. Hereinafter, the substrate treating apparatus and a semiconductor manufacturing facility including the same will be first described, and then the heating device will be described.

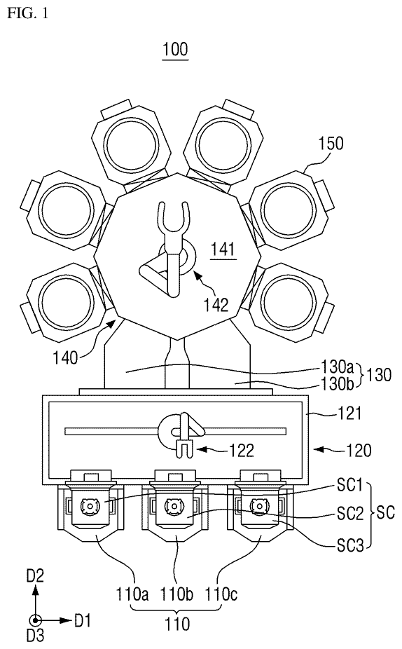

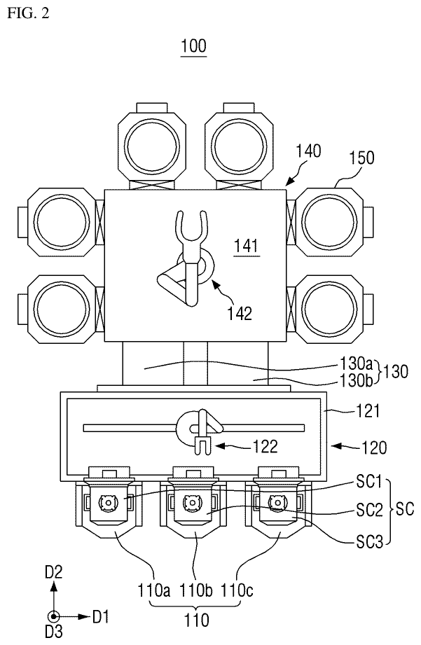

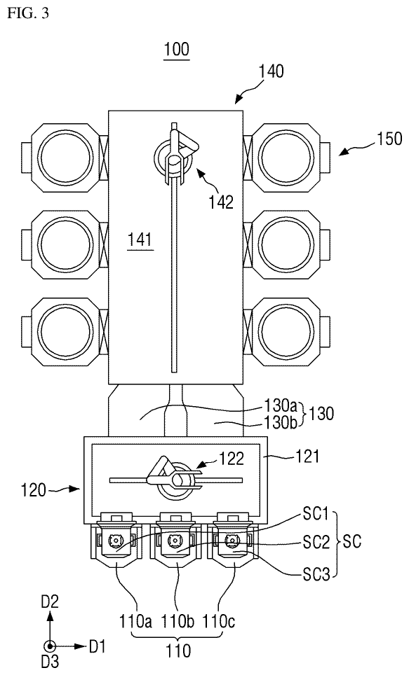

FIG. 1 is a first exemplary view schematically illustrating an internal structure of a semiconductor manufacturing facility for treating a substrate. FIG. 2 is a second exemplary view schematically illustrating an internal structure of a semiconductor manufacturing facility for treating a substrate. FIG. 3 is a third exemplary view schematically illustrating an internal structure of a semiconductor manufacturing facility for treating a substrate.

A first direction D1 and a second direction D2 constitute a plane in a horizontal direction. For example, the first direction D1 may be a front-rear direction, and the second direction D2 may be a left-right direction. Alternatively, the first direction D1 may be a left-right direction, and the second direction D2 may be a front-rear direction. A third direction D3 is a height direction, and is a direction perpendicular to a plane constituted by the first direction D1 and the second direction D2. The third direction D3 may be a vertical direction.

According to FIGS. 1 to 3, a semiconductor manufacturing facility 100 may include a load port module 110, an index module 120, a load lock chamber 130, a transfer module 140, and a process chamber 150.

The semiconductor manufacturing facility 100 is a system that treats a substrate by using an etching process, a cleaning process, a deposition process, or the like. The semiconductor manufacturing facility 100 may include one process chamber, but may include a plurality of process chambers without being limited thereto. The plurality of process chambers may include the same kind of process chambers, but may include different kinds of process chambers without being limited thereto. When the semiconductor manufacturing facility 100 includes a plurality of process chambers, it may be provided as a multi-chamber substrate treating system.

The load port module 110 is provided to allow a container SC, on which a plurality of substrates are mounted, to be seated thereon. For example, the container SC may be a Front Opening Unified Pod (FOUP).

In the load port module 110, the container SC may be loaded or unloaded. Also, in the load port module 110, the substrate accommodated in the container SC may be loaded or unloaded.

When a loading or unloading target is the container SC, a container carrying device may load or unload the container SC on or from the load port module 110. In detail, the container SC gripped by the container carrying device may be seated on the load port module 110, thereby loading the container SC on the load port module 110. In addition, the container carrying device may unload the container SC from the load port module 110 by gripping the container SC seated on the load port module 110. Although not shown in FIGS. 1 to 3, the container carrying device may be an Overhead Hoist Transporter (OHT).

When the loading or unloading target is the substrate, a first transfer robot 122 may load or unload the substrate from the container SC seated on the load port module 110. In case of unloading of the substrate, when the container SC is seated on the load port module 110, the first transfer robot 122 may access the load port module 110 and then may take out the substrate from the container SC. In case of loading of the substrate, when the substrate is completely treated in the process chamber 150, the first transfer robot 122 may take out the substrate from the load lock chamber 130 and then carry the substrate into the container SC.

The load port module 110 may be disposed in front of the index module 120 as a plural number. For example, three load port modules 110a, 110b and 110c such as a first load port module 110a, a second load port module 110b and a third load port module 110c may be disposed in front of the index module 120.

When the plurality of load port modules 110 are disposed in front of the index module 120, the container SC seated on each load port module may be loaded with different types of objects. For example, when the first load port module 110a, the second load port module 110b and the third load port module 110c are disposed in front of the index module 120, a first container SC1 seated on the first load port module 110a may be loaded with a wafer-type sensor, a second container SC2 seated on the second load port module 110b may be loaded with the substrate, that is, a wafer, and a third container SC3 seated on the third load port module 110c may be loaded with consumable components such as a focus ring and an edge ring.

However, the present embodiment is not limited to the above example. The container SC seated on each load port module may be loaded with the same types of objects. Alternatively, among the plurality of load port modules, the containers seated on some load port modules may be loaded with the same type of objects, and the containers seated on some other load port modules may be loaded with different types of objects.

The index module 120 is disposed between the load port module 110 and the load lock chamber 130, and may be provided as an interface so that the substrate may be transferred between the container SC on the load port module 110 and the load lock chamber 130.

The index module 120 may include a first module housing 121 and a first transfer robot 122. The first transfer robot 122 is disposed inside the first module housing 121, and may transfer the substrate between the load port module 110 and the load lock chamber 130. An internal environment of the first module housing 121 is provided as an atmospheric pressure environment, and the first transfer robot 122 may be operated in the atmospheric pressure environment. One first transfer robot 122 may be provided in the first module housing 121, but the present disclosure is not limited thereto, and a plurality of first transfer robots 122 may be also provided.

Although not shown in FIGS. 1 to 3, the index module 120 may include a buffer chamber. The buffer chamber may temporarily store an untreated substrate before being transferred to the load lock chamber 130. Further, the buffer chamber may temporarily store a pre-treated substrate before being transferred to the container SC on the load port module 110. The buffer chamber may be provided on the other sidewalls except a sidewall adjacent to the load port module 110 or a sidewall adjacent to the load lock chamber 130, but the present disclosure is not limited thereto, and may be also provided on the sidewall adjacent to the load port module 110. Alternatively, the buffer chamber may be provided on the sidewall adjacent to the load lock chamber 130.

In the present embodiment, a front end module FEM may be provided on one side of the load lock chamber 130. The front end module FEM may include a load port module 110 and an index module 120, and for example, may be provided as an Equipment Front End Module (EFEM).

As described above, the load port module 110 may be provided in the semiconductor manufacturing facility 100 as a plural number. Referring to the examples of FIGS. 1 to 3, a plurality of load port modules may have a structure in which they are arranged in a horizontal direction D1, but the present disclosure is not limited thereto. The plurality of load port modules may also have a structure in which they are stacked in a vertical direction D3. When the plurality of load port modules are stacked in the vertical direction, the front end module may be provided as a vertically stacked EFEM.

The load lock chamber 130 may serve as a buffer chamber between an input port and an output port in the semiconductor manufacturing facility 100. That is, the load lock chamber 130 may serve to temporarily store the untreated substrate or the pre-treated substrate between the load port module 110 and the process chamber 150. Although not shown in FIGS. 1 to 3, the load lock chamber 130 may include a buffer stage for temporarily storing the substrate therein.

The load lock chamber 130 may be disposed between the index module 120 and the transfer module 140 as a plural number. For example, two load lock chambers 130a and 130b, such as a first load lock chamber 130a and a second load lock chamber 130b, may be disposed between the index module 120 and the transfer module 140.

The plurality of load lock chambers may be disposed in the same direction as an arrangement direction of the plurality of load port modules. Referring to the examples of FIGS. 1 to 3, the first load lock chamber 130a and the second load lock chamber 130b may be disposed in the same direction as the arrangement direction of the three load port modules 110a, 110b, and 110c between the index module 120 and the transfer module 140, i.e., in the horizontal direction D1. The first load lock chamber 130a and the second load lock chamber 130b may be provided in a mutually symmetrical single layered structure in which they are disposed to be spaced apart from each other in the horizontal direction.

However, the present embodiment is not limited to the above example. The plurality of load lock chambers may be disposed in a direction different from the arrangement direction of the plurality of load port modules. The first load lock chamber 130a and the second load lock chamber 130b may be disposed in a direction different from the arrangement direction of the three load port modules 110a, 110b and 110c between the index module 120 and the transfer module 140, i.e., in the vertical direction D3. The first load lock chamber 130a and the second load lock chamber 130b may be provided in a double-layered structure in which they are disposed to be spaced apart from each other in the vertical direction.

Any one of the first load lock chamber 130a and the second load lock chamber 130b may temporarily store the untreated substrate transferred from the index module 120 to the transfer module 140. Furthermore, the other load lock chamber may temporarily store the pre-treated substrate transferred from the transfer module 140 to the index module 120. However, the present disclosure is not limited to the above example. The first load lock chamber 130a and the second load lock chamber 130b may commonly serve as both a temporary storage of the untreated substrate and a temporary storage of the pre-treated substrate.

The load lock chamber 130 may change its inside to any one of a vacuum environment and an atmospheric pressure environment by using a gate valve or the like. In detail, when the first transfer robot 122 of the index module 120 loads the substrate into the load lock chamber 130 or the first transfer robot 122 unloads the substrate from the load lock chamber 130, the load lock chamber 130 may form its inside to an environment the same as or similar to an internal environment of the index module 120. Furthermore, when the second transfer robot 142 of the transfer module 140 loads the substrate into the load lock chamber 130 or the second transfer robot 142 unloads the substrate from the load lock chamber 130, the load lock chamber 130 may form the inside thereof to an environment the same as or similar to an internal environment of the transfer module 140. Therefore, the load lock chamber 130 may prevent an inner air pressure state of the index module 120 or an inner air pressure state of the transfer module 140 from being changed.

The transfer module 140 is disposed between the load lock chamber 130 and the process chamber 150, and may be provided as an interface so that the substrate may be transferred between the load lock chamber 130 and the process chamber 150.

The transfer module 140 may include a second module housing 141 and a second transfer robot 142. The second transfer robot 142 is disposed inside the second module housing 141, and may transfer the substrate between the load lock chamber 130 and the process chamber 150. An internal environment of the second module housing 141 is provided as a vacuum environment, and the second transfer robot 142 may operate in a vacuum environment. One second transfer robot 142 may be provided inside the second module housing 141, but may be provided as a plural number without being limited thereto.

The transfer module 140 may be connected to the plurality of process chambers 150. To this end, the second module housing 141 may include a plurality of sides, and the second transfer robot 142 may be freely rotated through each side of the second module housing 141 so that the substrate may be loaded in the plurality of process chambers 150 or may be unloaded from the plurality of process chambers 150.

The process chamber 150 serves to treat the substrate. When the untreated substrate is provided, the process chamber 150 may treat the substrate and provide the pre-treated substrate to the load lock chamber 130 through the transfer module 140. A more detailed description of the process chamber 150 will be given later.

When the semiconductor manufacturing facility 100 includes the plurality of process chambers, the semiconductor manufacturing facility 100 may be formed in a structure having a cluster platform. For example, the plurality of process chambers may be disposed in a cluster manner based on the transfer module 140 as illustrated in FIG. 1, but the present embodiment is not limited thereto. When the semiconductor manufacturing facility 100 includes the plurality of process chambers, the semiconductor manufacturing facility 100 may be formed in a structure having a quad platform. For example, the plurality of process chambers may be disposed in a quad manner based on the transfer module 140 as illustrated in the example of FIG. 2. Alternatively, when the semiconductor manufacturing facility 100 includes the plurality of process chambers, the semiconductor manufacturing facility 100 may be formed in a structure having an in-line platform. For example, the plurality of process chambers may be disposed in an in-line manner based on the transfer module 140 as illustrated in the example of FIG. 3, and two different process chambers may be disposed in series while forming a corresponding relationship on both sides of the transfer module 140.

Although not shown in FIGS. 1 to 3, the semiconductor manufacturing facility 100 may further include a control device. The control device serves to control the entire operation of each module constituting the semiconductor manufacturing facility 100. For example, the control device may control the substrate transfer of the first transfer robot 122 or the second transfer robot 142, control a change in the internal environment of the load lock chamber 130 and control an overall substrate treating process of the process chamber 150.

The control device may include a processor for controlling each component constituting the semiconductor manufacturing facility 100, a network for wired or wireless communication with each component, one or more instructions related to a function or operation for controlling each component, a storage means for storing processing recipes including the instructions, various data, and the like. In addition, the control device may further include a user interface that includes an input means for allowing an operator to perform a command input manipulation or the like to manage the semiconductor manufacturing facility 100 and an output means for visualizing and displaying an actuation status of the semiconductor manufacturing facility 100. The control device may be provided as a computing device for data processing, analysis, and command transmission.

The instruction may be provided in the form of a computer program or an application. The computer program may include one or more instructions and thus may be stored in a computer-readable recording medium. The instruction may include a code generated by a compiler, a code capable of being executed by an interpreter, and the like. The storage means may be provided as one or more storage media selected from a flash memory, an HDD, an SSD, a card type memory, a RAM, an SRAM, a ROM, an EEPROM, a PROM, a magnetic memory, a magnetic disk and an optical disk.

Next, the process chamber 150 will be described. A surface of the process chamber 150 may be made of alumite formed with an anodized film, and an inside thereof may be configured to be air tight. The process chamber 150 may be provided in the semiconductor manufacturing facility 100 as a plural number, and the plurality of process chambers may be disposed to be spaced apart from each other around the transfer module 140, but the present disclosure is not limited thereto, and the process chamber 150 may be also provided in the semiconductor manufacturing facility 100 as a single number. The process chamber 150 may be provided in a cylindrical shape, but is not limited thereto, and may be provided in a shape other than the cylindrical shape.

As described above, the process chamber 150 may treat the substrate. Hereinafter, the process chamber 150 will be defined as the substrate treating apparatus and the internal structure of the process chamber 150 will be described.

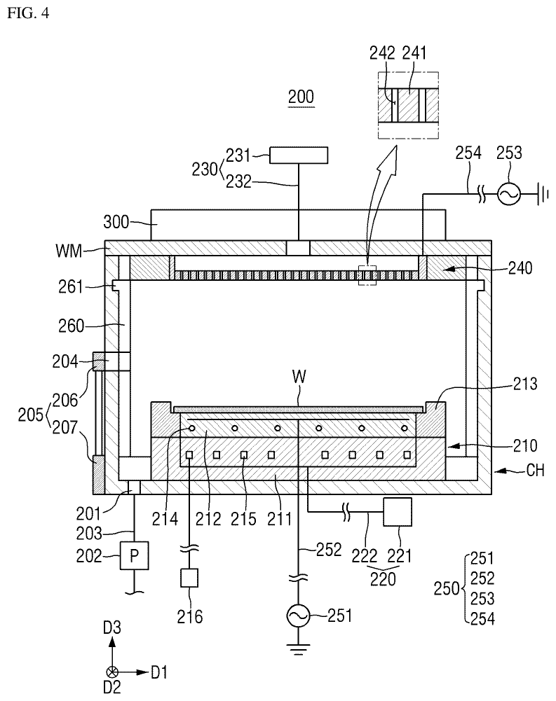

FIG. 4 is a first exemplary view illustrating an internal structure of a substrate treating apparatus constituting a semiconductor manufacturing facility in a cross-sectional view. According to FIG. 4, the substrate treating apparatus 200 may include a chamber housing CH, a substrate support unit 210, a cleaning gas supply unit 220, a process gas supply unit 230, a showerhead unit 240, a plasma generating unit 250, a liner unit 260, a window module WM, and a heating device 300.

The substrate treating apparatus 200 may treat the substrate W by using plasma. The substrate treating apparatus 200 may treat the substrate W in a dry method. The substrate treating apparatus 200 may treat the substrate W, for example, in a vacuum environment. The substrate treating apparatus 200 may treat the substrate W by using an etching process, but is not limited thereto, and the substrate treating apparatus 200 may also treat the substrate W by using a deposition process or a cleaning process.

The chamber housing CH provides a space in which a process of treating the substrate W by using plasma, that is, a plasma process is executed. The chamber housing CH may have an exhaust hole 201 in a lower portion thereof.

The exhaust hole 201 may be connected to an exhaust line 203 on which a pump 202 is mounted. The exhaust hole 201 may discharge reaction by-products generated during the plasma process and a gas remaining inside the chamber housing CH to the outside of the chamber housing CH through the exhaust line 203. In this case, an inner space of the chamber housing CH may be decompressed.

An opening 204 may be formed to pass through a sidewall of the chamber housing CH. The opening 204 may be provided as a passage through which the substrate W enters and exits the chamber housing CH. The opening 204 may be configured to be automatically opened and closed by, for example, a door assembly 205.

The door assembly 205 may include an outer door 206 and a door driver 207. The outer door 206 may open and close the opening 204 on an outer wall of the chamber housing CH. The outer door 206 may be moved in the height direction D3 of the substrate treating apparatus 200 under the control of the door driver 207. The door driver 207 may operate using at least one element selected from a motor, a hydraulic cylinder and a pneumatic cylinder.

The substrate support unit 210 is installed in an inner lower zone of the chamber housing CH. The substrate support unit 210 may adsorb and support the substrate W by using an electrostatic force, but is not limited thereto, and the substrate support unit 210 may support the substrate W by using various other methods such as vacuum and mechanical clamping.

The substrate support unit 210 may include a base 211 and an electrostatic chuck 212 when supporting the substrate W by using an electrostatic force. An electrostatic chuck (ESC) 212 is disposed on the base 211, and may support the substrate W seated thereon by using an electrostatic force. The base 211 may be provided as, for example, an aluminum body. The electrostatic chuck 212 may be formed of, for example, a ceramic material.

The ring structure 213 is provided to surround an outer edge zone of the electrostatic chuck 212. The ring structure 213 may serve to concentrate ions on the substrate W when the plasma process is performed inside the chamber housing CH. The ring structure 213 may be formed of a silicon material. For example, the ring structure 213 may be provided as a focus ring.

Although not shown in FIG. 4, the substrate treating apparatus 200 may further include an edge ring provided to surround an outer zone of the ring structure 213. The edge ring may serve to prevent a side of the electrostatic chuck 212 from being damaged by plasma. The edge ring may be formed of an insulator material, for example, quartz.

A heating member 214 and a cooling member 215 are provided to maintain the substrate W at a process temperature when the substrate treating process is performed inside the chamber housing CH. The heating member 214 may be provided as a heating wire to increase the temperature of the substrate W. For example, the heating member 214 may be installed inside the electrostatic chuck 212. The cooling member 215 may be provided as a cooling line through which a refrigerant flows in order to lower the temperature of the substrate W. For example, the cooling member 215 may be installed inside the base 211. A cooling device (chiller) 216 may supply the refrigerant to the cooling member 215. The cooling device 216 may use cooling water as the refrigerant, but is not limited thereto, and may further use helium (He) gas. Alternatively, the cooling device 216 may use any one of cooling water and helium gas as the refrigerant.

The cleaning gas supply unit 220 provides a cleaning gas to the electrostatic chuck 212 or the ring structure 213 to remove particles remaining in the electrostatic chuck 212 or the ring structure 213. For example, the cleaning gas supply unit 220 may provide nitrogen (N₂) gas as the cleaning gas.

The cleaning gas supply unit 220 may include a cleaning gas supply source 221 and a cleaning gas supply line 222. The cleaning gas supply line 222 may be connected to a space between the electrostatic chuck 212 and the ring structure 213. The cleaning gas supplied by the cleaning gas supply source 221 may move to a space between the electrostatic chuck 212 and the ring structure 213 through the cleaning gas supply line 222 to remove particles remaining in an edge portion of the electrostatic chuck 212 or an upper portion of the ring structure 213.

The process gas supply unit 230 provides a process gas to the inner space of the chamber housing CH. The process gas supply unit 230 may provide the process gas to the inner space of the chamber housing CH through a hole formed by passing through an upper cover of the chamber housing CH, that is, the window module WM, but is not limited thereto. The process gas supply unit 230 may also provide the process gas to the inner space of the chamber housing CH through a hole formed by passing through the sidewall of the chamber housing CH.

The process gas supply unit 230 may include a process gas supply source 231 and a process gas supply line 232. The process gas supply source 231 may provide a gas used for treating the substrate W as the process gas. The process gas supply source 231 may be provided in the substrate treating apparatus 200 as a single number, but may be provided as a plural number without being limited thereto. When the process gas supply source 231 is provided in the substrate treating apparatus 200 as a plural number, the plurality of process gas supply sources 231 may provide the same type of process gas, but are not limited thereto, and may provide different types of process gases.

The showerhead unit 240 sprays the process gas provided from the process gas supply source 231 onto the entire zone of the substrate W disposed in the inner space of the chamber housing CH. The showerhead unit 240 may be connected to the process gas supply source 231 through the process gas supply line 232.

The showerhead unit 240 is disposed in the inner space of the chamber housing CH, and may include a plurality of gas feeding holes 242. The plurality of gas feeding holes 242 may be formed to pass through a surface of a body 241 of the showerhead unit 240 in the vertical direction D3. The plurality of gas feeding holes 242 may be formed on the body 241 so that they are spaced apart from each other at a predetermined interval. The showerhead unit 240 may uniformly spray the process gas to the entire zone of the substrate W through the plurality of gas feeding holes 242.

The showerhead unit 240 may be installed inside the chamber housing CH to face the electrostatic chuck 212 in the vertical direction D3. The showerhead unit 240 may be provided to have a larger diameter than the electrostatic chuck 212, but is not limited thereto. The showerhead unit 240 may be provided to have the same diameter as that of the electrostatic chuck 212. The showerhead unit 240 may be formed of a silicon material, but is not limited thereto. The showerhead unit 240 may be also formed of a metal material.

Although not shown in FIG. 4, the showerhead unit 240 may be divided into a plurality of units. For example, the showerhead unit 240 may be divided into three units such as a first unit, a second unit and a third unit. The first unit may be disposed at a position corresponding to a center zone of the substrate W. The second unit may be disposed to surround an outer edge of the first unit. The second unit may be disposed at a position corresponding to a middle zone of the substrate W. The third unit may be disposed to surround an outer edge of the second unit. The third unit may be disposed at a position corresponding to an edge zone of the substrate W.

Although not shown in FIG. 4, when the showerhead unit 240 is divided into a plurality of units, the process gas supply unit 230 may include a process gas distributor and a process gas distribution line to distribute the process gas to each unit of the showerhead unit 240 The process gas distributor is installed on the process gas supply line 232, and may distribute the process gas supplied from the process gas supply source 231 to each unit of the showerhead unit 240 through the process gas distribution line. The process gas distribution line may be a portion of the process gas supply line 232, and may connect the process gas distributor with each unit of the showerhead unit 240.

The plasma generating unit 250 generates plasma from a gas remaining in a discharge space. In this case, the discharge space is the inner space of the chamber housing CH, and may be a space formed between the showerhead unit 240 and the window module WM. Alternatively, the discharge space may be a space formed between the substrate support unit 210 and the showerhead unit 240. When the discharge space is the space formed between the substrate support unit 210 and the showerhead unit 240, the discharge space may be divided into a plasma zone and a process zone. The plasma zone may be formed to be higher than the process zone.

The plasma generating unit 250 may generate plasma in the discharge space by using a capacitively coupled plasma (CCP) source. For example, the plasma generating unit 250 may generate plasma in the discharge space by using the electrostatic chuck 212 as a first electrode (lower electrode) and the second showerhead unit 240 as a second electrode (upper electrode), but the present embodiment is not limited thereto.

The plasma generating unit 250 may generate plasma in the discharge space by using an inductively coupled plasma (ICP) source. For example, the plasma generating unit 250 may generate plasma in the discharge space by using the electrostatic chuck 212 as a first electrode (lower electrode) and the antenna unit 270 as a second electrode (upper electrode). The case that the plasma generating unit 250 uses the ICP source will be described later.

The plasma generating unit 250 may include a first high frequency power source 251, a first transmission line 252, a second high frequency power source 253, and a second transmission line 254.

The first high frequency power source 251 applies RF power to the first electrode. The first high frequency power source 251 may serve as a plasma source for generating plasma in the chamber housing CH.

The first high frequency power source 251 may be provided in the substrate treating apparatus 200 as a single number, but is not limited thereto, and may be provided as a plural number. When the first high frequency power source 251 is provided in the substrate treating apparatus 200 as a plural number, the plurality of first high frequency power sources 251 may be disposed on the first transmission line 252 in parallel.

Although not shown in FIG. 4, when the first high frequency power source 251 is provided in the substrate treating apparatus 200 as a plural number, the plasma generating unit 250 may include a first matching network electrically connected to each of the first high frequency power sources. The first matching network may serve to match the frequency powers and apply them to the first electrode when frequency powers of different magnitudes are input from the plurality of first high frequency power sources.

The first transmission line 252 may connect the first electrode to GND. The first high frequency power source 251 may be installed on the first transmission line 252, but is not limited thereto. The first transmission line 252 may connect the first electrode to the first high frequency power source 251. For example, the first transmission line 252 may be provided as an RF rod.

Although not shown in FIG. 4, a first impedance matching circuit may be provided on the first transmission line 252 connecting the first high frequency power source 251 with the first electrode for the purpose of impedance matching. The first impedance matching circuit may act as a lossless passive circuit, and may allow the maximum amount of electrical energy to be transferred from the first high frequency power source 251 to the first electrode.

The second high frequency power source 253 applies RF power to the second electrode. The second high frequency power source 253 may serve to control characteristics of plasma in the chamber housing CH. For example, the second high frequency power source 253 may serve to control ion bombardment energy in the chamber housing CH.

The second high frequency power source 253 may be provided in the substrate treating apparatus 200 as a plural number. When the second high frequency power source 253 is provided in the substrate treating apparatus 200 as a plural number, the second high frequency power sources 253 may be disposed in parallel on the second transmission line 254.

Although not shown in FIG. 4, when the second high frequency power source 253 is provided in the substrate treating apparatus 200 as a plural number, the plasma generating unit 250 may include a second matching network electrically connected to each of the second high frequency power sources. The second matching network may serve to match the frequency powers and apply them to the second electrode when frequency powers of different magnitudes are input from the plurality of second high frequency power sources.

The second transmission line 254 connects the second electrode to the GND. The second high frequency power source 253 may be installed on the second transmission line 254.

Although not shown in FIG. 4, a second impedance matching circuit may be provided on the second transmission line 254 connecting the second high frequency power source 252 with the second electrode for the purpose of impedance matching. The second impedance matching circuit may act as a lossless passive circuit, and may allow the maximum amount of electrical energy to be transferred from the second high frequency power source 253 to the second electrode.

Meanwhile, the first high frequency power source 251 may serve to control characteristics of plasma inside the chamber housing CH in the same manner as the second high frequency power source 253.

The liner unit 260 may be defined as a wall liner, and protects the inside of the chamber housing CH from arc discharge occurring during a process of exciting a process gas or impurities generated during the substrate treating process. The liner unit 260 may be formed to cover an inner wall of the chamber housing CH.

The liner unit 260 may include a support ring 261 on an upper portion of a body. The support ring 261 may be protruded from the upper portion of the body in an outward direction D1, and may serve to fix the body to the chamber housing CH.

The window module WM serves as an upper cover of the chamber housing CH, which seals the inner space of the chamber housing CH. The window module WM may be provided separately from the chamber housing CH, but is not limited thereto, and may be also provided as a portion of the chamber housing CH. When provided separately from the chamber housing CH, the window module WM may cover the open upper portion of the chamber housing CH. When provided as a portion of the chamber housing CH, the window module WM may be provided integrally with the chamber housing CH.

The heating device 300 may provide energy to a space inside the chamber housing CH, in which the substrate W is treated, to heat the substrate W disposed on the substrate support unit 210. The energy provided by the heating device 300 may accelerate a reaction between the substrate W and the process gas. The heating device 300 may rapidly heat the inside of the chamber housing CH. The heating device 300 may be a rapid thermal source. For example, the heating device 300 may be provided as a flash lamp that generates a flash, a laser unit that generates and transfers a laser, a microwave unit that generates microwaves, and the like. The heating device 300 may provide energy required for a reaction by using at least one of a flash lamp, a laser unit or a microwave unit.

The heating device 300 may uniformly maintain an internal temperature of the chamber housing CH while a process of treating the substrate W inside the chamber housing CH is being performed. The heating device 300 may uniformly maintain a surface temperature of the substrate W. The heating device 300 may uniformly maintain the surface temperature of the substrate W for each zone. The heating device 300 may shorten the time required to complete the process of treating the substrate W.

The heating device 300 may operate simultaneously with the plasma generating unit 250. That is, the heating device 300 may have an operation start time point and an operation end time point, which are the same as those of the plasma generating unit 250, but is not limited thereto. The heating device 300 may not operate simultaneously with the plasma generating unit 250. That is, the heating device 300 may have at least one of an operation start time point and an operation end time point, which is different from that of the plasma generating unit 250.

For example, the heating device 300 may have an operation start time point earlier than the plasma generating unit 250. Otherwise, the heating device 300 may have an operation start time point later than the plasma generating unit 250. Otherwise, the heating device 300 may have an operation end time point earlier than the plasma generating unit 250. Otherwise, the heating device 300 may have an operation end time point later than the plasma generating unit 250. Otherwise, the heating device 300 may be faster than the plasma generating unit 250 at both the operation start time point and the operation end time point. Otherwise, the heating device 300 may be later than the plasma generating unit 250 at both the operation start time point and the operation end time point. Otherwise, the heating device 300 may have one of the operation start time point and the operation end time point, which is faster than the plasma generating unit 250, and the other one later than that of the plasma generating unit 250.

The heating device 300 may be installed outside the chamber housing CH. For example, the heating device 300 may be installed above the window module WM. The heating device 300 may be installed to be in contact with the window module WM. The heating device 300 may be installed to be spaced apart from the window module WM. When the heating device 300 is spaced apart from the window module WM, the heating device 300 may be connected to the window module WM through a connecting rod. Alternatively, the heating device 300 may be also connected to the window module WM through a connecting tube.

In the present disclosure, energy applied by the heating device 300 is preferably transferred to the substrate W without loss. When the heating device 300 is installed on the window module WM, the showerhead unit 240 and the window module WM may be formed of a material capable of transmitting energy. For example, the showerhead unit 240 and the window module WM may be formed of a transparent material or a light-transmitting material.

In the present disclosure, the heating device 300 may be provided as a microwave unit. That is, the heating device 300 may be provided as a microwave heater capable of heating the substrate W by using microwaves. The case that the heating device 300 is provided as a microwave heater will be described later.

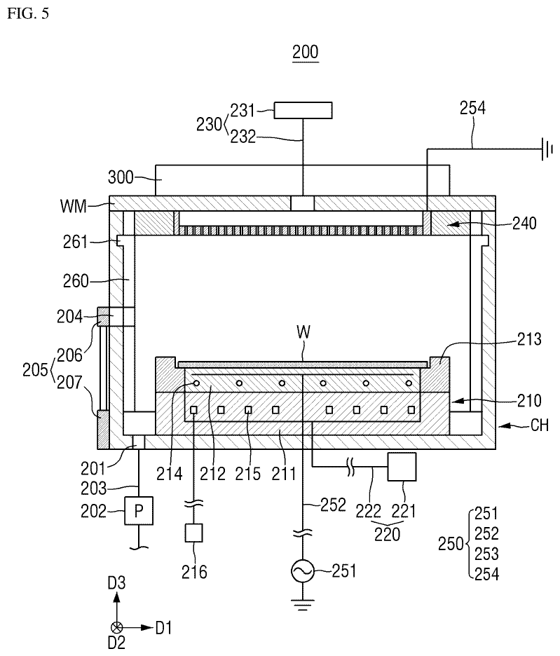

FIG. 5 is a second exemplary view illustrating an internal structure of a substrate treating apparatus constituting a semiconductor manufacturing facility in a cross-sectional view. Hereinafter, a description of redundant portions as compared with the case of FIG. 4 will be omitted, and only portions corresponding to differences therefrom will be described.

Referring to FIG. 5, the plasma generating unit 250 may include a first high frequency power source 251, a first transmission line 252, and a second transmission line 254. Referring to FIG. 4, the plasma generating unit 250 may include a first high frequency power source 251, a first transmission line 252, a second high frequency power source 253, and a second transmission line 254. The plasma generating unit 250 of FIG. 4 may further include a second high frequency power source 253 as compared with the plasma generating unit 250 of FIG. 5. The second high frequency power source 253 may be installed on the second transmission line 254. When the second high frequency power source 253 is installed on the second transmission line 254, the plasma generating unit 250 may apply a multi-frequency to the substrate treating apparatus 200.

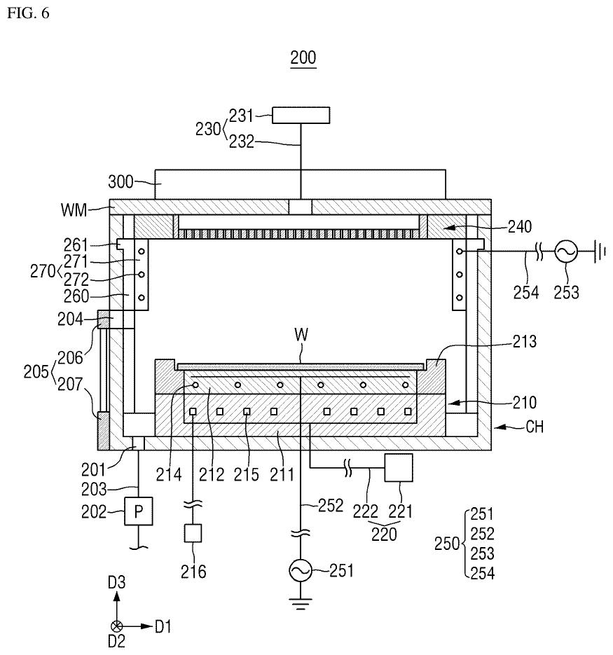

The case that the plasma generating unit 250 generates plasma in the discharge space by using the CCP source has been described with reference to FIGS. 4 and 5. Hereinafter, the case that the plasma generating unit 250 generates plasma in the discharge space by using the ICP source will be described with reference to FIG. 6. FIG. 6 is a third exemplary view illustrating an internal structure of a substrate treating apparatus constituting a semiconductor manufacturing facility in a cross-sectional view. Hereinafter, a description of redundant portions as compared with the case of FIG. 4 will be omitted, and only portions corresponding to differences therefrom will be described.

According to FIG. 6, the substrate treating apparatus 200 may include a chamber housing CH, a substrate support unit 210, a cleaning gas supply unit 220, a process gas supply unit 230, a showerhead unit 240, a plasma generating unit 250, a liner unit 260, a baffle unit 270, a window module WM, and an antenna unit 270. That is, the substrate treating apparatus 200 of FIG. 6 may further include an antenna unit 270 as compared with the substrate treating apparatus 200 of FIGS. 4 and 5.

The antenna unit 270 serves to excite the process gas into plasma by generating a magnetic field and an electric field inside the chamber housing CH. The antenna unit 270 may operate using RF power supplied from the second high frequency power source 253. The antenna unit 270 may be provided on the upper portion of the chamber housing CH. For example, the antenna unit 270 may be provided on the window module WM, but is not limited thereto, and the antenna unit 270 may be provided on the sidewall of the chamber housing CH.

The antenna unit 270 may include an antenna 272 inside or on a surface of a body 271. The antenna 272 may be provided to form a closed loop by using a coil. The antenna 272 may be formed in a spiral shape along a width direction D1 of the chamber housing CH or other various shapes.

The antenna unit 270 may be formed to have a planar type, but is not limited thereto, and the antenna unit 270 may be formed to have a cylindrical type. When the antenna unit 270 is formed to have a planar type, it may be provided on the upper portion of the chamber housing CH. When the antenna unit 270 is formed to have a cylindrical type, it may be provided to surround an outer sidewall of the chamber housing CH.

In case of the example according to FIG. 4, the second transmission line 254 may be connected to the body 241 of the showerhead unit 240. The second high frequency power source 253 may apply RF power to the body 241 of the showerhead unit 240. In case of the example according to FIG. 6, the second transmission line 254 may be connected to the antenna 272 of the antenna unit 270. The second high frequency power source 253 may apply RF power to the antenna 272 of the antenna unit 270.

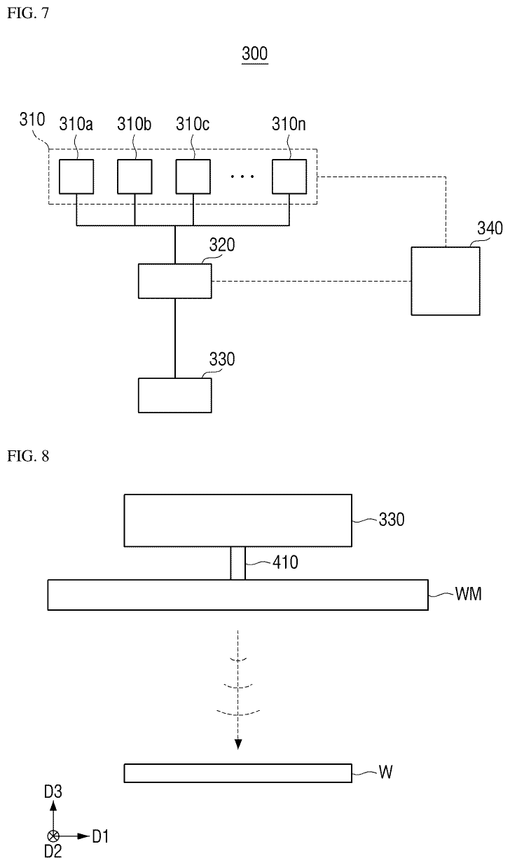

Next, the case that the heating device 300 is provided as the microwave heater will be described. FIG. 7 is a first exemplary view schematically illustrating an internal configuration of a heating device constituting a substrate treating apparatus. According to FIG. 7, the heating device 300 may include a microwave generating module 310, a microwave synthesis module 320, a waveguide 330, and a control module 340.

The heating device 300 may heat the substrate W by using microwaves, but is not limited thereto, and the heating device 300 may also heat the substrate W by using electromagnetic waves other than microwaves. Alternatively, the heating device 300 may heat the substrate W by using light. For example, the heating device 300 may heat the substrate W by using laser light. Alternatively, the heating device 300 may heat the substrate W by using flash light.

Since a wavelength of the microwave is much longer than a thickness and spacing of a metal wiring layer of a semiconductor, a depth at which the microwave is permeated into a metal material is less than several μm. When a surface of the substrate W is heated by microwave heat treatment, an effect of rapidly increasing the surface temperature of the substrate W to a target temperature may be obtained. When the substrate W is heated with the microwave, only the surface of the substrate W is selectively heated so that a heating rate and a cooling rate are fast, and the surface of the substrate W may be heated to a target temperature within a short time so that the process time may be shortened.

Among issues of Reactive Ion Etching (RIE) processes according to semiconductor fine patterns, the etching process technology in atomic layer units is in the spotlight as a future technology to increase uniformity and selectivity. Atomic Layer Etching (ALE), which is an etching process technology in atomic layer units, is a method of removing a controlled amount of material, and uses an adsorption reaction that modifies a film material of the surface and a desorption reaction that removes the modified film material. In this case, the adsorption reaction is relatively reactive at low temperature (e.g., room temperature or less), and the desorption reaction is relatively reactive at high temperature (e.g., 500° C. or more). When the substrate W is heated using microwaves, rapid heating and rapid cooling become possible, and a highly reactive temperature may be applied to each of the adsorption reaction and the desorption reaction.

Thermal ALE technology is required to shorten the time required for the etching process. The thermal ALE technology is applied to the heating device 300 of the present disclosure. The present disclosure proposes a plurality of microwave generators and controllers that generate high power and uniformity for mass-producing high-quality wafers in a short time, and a heating operation method. The heating device 300 of the present disclosure may be provided as a plurality of microwave heating systems capable of operating variable power and frequency for a substrate treating apparatus.

The microwave generating module 310 may generate microwaves. The microwave generating module 310 may be provided as a plural number. That is, the microwave generating module 310 may include ‘n’ number of generating modules 310a, 310b, 310c, . . . , 310n such as a first generating module 310a, a second generating module 310b, a third generating module 310c, . . . , an (n)th generating module 310n.

The plurality of microwave generating modules 310a, 310b, 310c, . . . , 310n may generate microwaves in a predetermined frequency range. For example, the plurality of microwave generating modules 310a, 310b, 310c, . . . , 310n may generate microwaves in the frequency range of 1 GHz to 10 GHz. Each of the microwave generating modules 310a, 310b, 310c, . . . , 310n may generate microwaves having a frequency value selected from 1 GHz to 10 GHz.

The plurality of microwave generating modules 310a, 310b, 310c, . . . , 310n may generate microwaves having different frequency values. For example, the first generating module 310a may generate a microwave having a first frequency value, the second generating module 310b may generate a microwave having a second frequency value, and the third generating module 310c may generate a microwave having a third frequency value. The first frequency value may be different from the second frequency value. The first frequency value may be greater than the second frequency value. Alternatively, the first frequency value may be smaller than the second frequency value. The first frequency value may be different from the third frequency value. The first frequency value may be greater than the third frequency value. Alternatively, the first frequency value may be smaller than the third frequency value. The second frequency value may be different from the third frequency value. The second frequency value may be greater than the third frequency value. Alternatively, the second frequency value may be smaller than the third frequency value.

However, the present disclosure is not limited to the above example. Some of the microwave generating modules 310a, 310b, 310c, . . . , 310n may generate microwaves having the same frequency value, and some other microwave generating modules may generate microwaves having different frequency values. For example, the first frequency value and the second frequency value may be the same as each other, and the third frequency value may be different from the first frequency value and the second frequency value. The third frequency value may be greater than the first frequency value and the second frequency value. Alternatively, the third frequency value may be smaller than the first frequency value and the second frequency value.

The plurality of microwave generating modules 310a, 310b, 310c, . . . , 310n may generate microwaves having different amounts of power. For example, the first generating module 310a may generate a microwave having a first amount of power, the second generating module 310b may generate a microwave having a second amount of power, and the third generating module 310c may generate a microwave having a third amount of power. The first amount of power may be different from the second amount of power. The first amount of power may be greater than the second amount of power. Alternatively, the first amount of power may be smaller than the second amount of power. The first amount of power may be different from the third amount of power. The first amount of power may be greater than the third amount of power. Alternatively, the first amount of power may be smaller than the third amount of power. The second amount of power may be different from the third amount of power. The second amount of power may be greater than the third amount of power. Alternatively, the second amount of power may be smaller than the third amount of power.

However, the present disclosure is not limited to the above example. Some of the microwave generating modules 310a, 310b, 310c, . . . , 310n may generate microwaves having the same amount of power, and some other microwave generating modules may generate microwaves having different amounts of power. For example, the first amount of power and the second amount of power may be the same as each other, and the third amount of power may be different from the first amount of power and the second amount of power. The third amount of power may be greater than the first amount of power and the second amount of power. Alternatively, the third amount of power may be smaller than the first amount of power and the second amount of power.

The plurality of microwave generating modules 310a, 310b, 310c, . . . , 310n may generate microwaves having different phases. For example, the first generating module 310a may generate a microwave having a first phase, the second generating module 310b may generate a microwave having a second phase, and the third generating module 310c may generate a microwave having a third phase. The first phase may be different from the second phase. The first phase may be greater than the second phase. Alternatively, the first phase may be smaller than the second phase. The first phase may be different from the third phase. The first phase may be greater than the third phase. Alternatively, the first phase may be smaller than the third phase. The second phase may be different from the third phase. The second phase may be greater than the third phase. Alternatively, the second phase may be smaller than the third phase.

However, the present disclosure is not limited to the above example. Some of the microwave generating modules 310a, 310b, 310c, . . . , 310n may generate microwaves having the same phase, and some other microwave generating modules may generate microwaves having different phases. For example, the first phase and the second phase may be the same as each other, and the third phase may be different from the first phase and the second phase. The third phase may be greater than the first phase and the second phase. Alternatively, the third phase may be smaller than the first phase and the second phase.

The microwave synthesis module 320 may synthesize a plurality of microwaves generated by the plurality of microwave generating modules 310a, 310b, 310c, . . . , 310n. The microwave synthesis module 320 may generate a composite wave by synthesizing a plurality of microwaves. The microwave synthesis module 320 may be provided as a mixer.

When any one of the plurality of microwave generating modules 310a, 310b, 310c, . . . , 310n operates, the microwave synthesis module 320 may not operate. Considering this case, the microwave synthesis module 320 may not be included in the heating device 300.

The waveguide 330 may transfer the synthesized wave generated by the microwave synthesis module 320 to the inside of the chamber housing CH. Alternatively, The waveguide 330 may transmit the microwave output by any one of the plurality of microwave generating modules 310a, 310b, 310c, . . . , 310n to the inside of the chamber housing CH.

The waveguide 330 may connect the microwave synthesis module 320 with the chamber housing CH. For example, the waveguide 330 may connect the microwave synthesis module 320 with the window module WM. The waveguide 330 may use a TE10 mode, but is not limited thereto. The waveguide 330 may use various types of TE_mn modes and TM_mn modes. In this case, ‘m’ and ‘n’ are integers. The waveguide 330 may use a coaxial type TEM mode.

The waveguide 330 may be in close contact with an upper portion of the window module WM in order to transfer the composite wave to the inside of the chamber housing CH through the window module WM, but the present disclosure is not limited thereto. The waveguide 330 may be spaced apart from the upper portion of the window module WM. In this case, a connecting rod or a connecting tube may connect the waveguide 330 with the window module WM.

The connecting rod 410 may be provided as a single number to connect the waveguide 330 with the window module WM. Referring to FIG. 8, the connecting rod 410 may connect the waveguide 330 to a portion of the window module WM, which corresponds to a center zone of the substrate W. FIG. 8 is a first exemplary view illustrating an embodiment of a waveguide constituting a heating device.

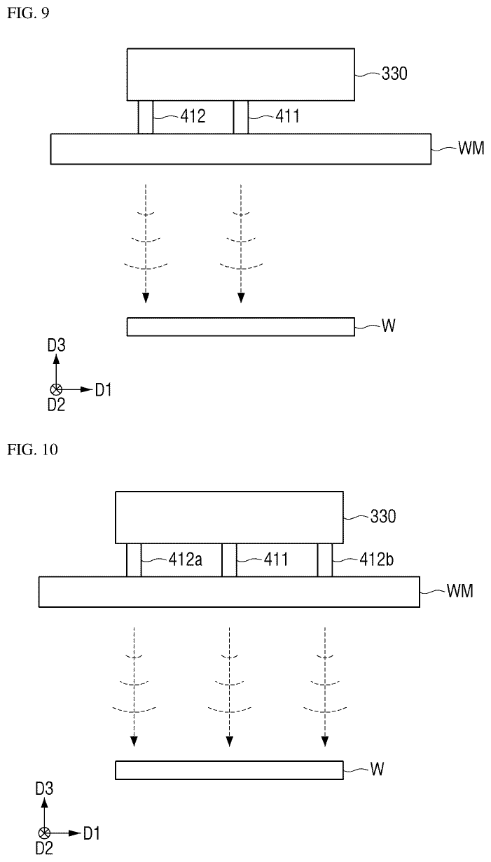

The connecting rod 410 may be provided as a plural number to connect the waveguide 330 with the window module WM. Referring to FIG. 9, the connecting rod 410 may include a first rod 411 and a second rod 412. The first rod 411 may connect the waveguide 330 to a center zone of the window module WM. The second rod 412 may connect the waveguide 330 to an edge zone of the window module WM. The center zone of the window module WM may be formed at a position corresponding to the center zone of the substrate W in the vertical direction D3. The edge zone of the window module WM may be formed at a position corresponding to the edge zone of the substrate W in the vertical direction D3. The first rod 411 may heat the center zone of the substrate W by transferring microwaves to the center zone of the substrate W. The second rod 412 may heat the edge zone of the substrate W by transferring microwaves to the edge zone of the substrate W. FIG. 9 is a second exemplary view illustrating an embodiment of a waveguide constituting a heating device.

The second rod 412 may be provided in the same number as the first rod 411. For example, the connecting rod 410 may include one first rod 411 and one second rod 412, but is not limited thereto, and the number of the second rod 412 may be different from the number of the first rod 411. The second rod 412 may be provided as a larger number of rods than the first rod 411. Referring to FIG. 10, the connecting rod 410 may include one first rod 411 and two second rods 412a and 412b. Two second rods 412a and 412b may be disposed at both sides of the first rod 411. FIG. 10 is a third exemplary view illustrating an embodiment of a waveguide constituting a heating device.

An example of FIGS. 9 and 10 is an example of dividing the window module WM into two zones, but the present disclosure is not limited thereto, and the window module WM may be divided into three or more zones. For example, the window module WM may be divided into three zones, a center zone, a middle zone, and an edge zone.

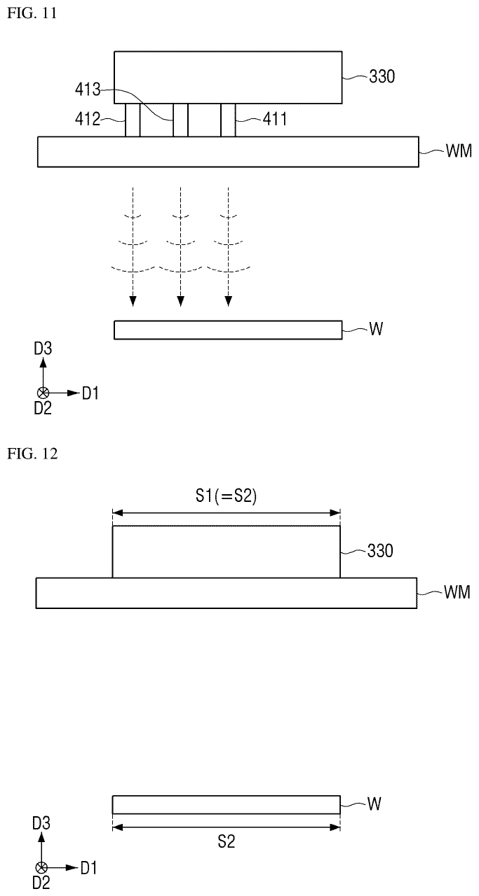

Referring to FIG. 11, the connecting rod 410 may include a first rod 411, a second rod 412, and a third rod 413. The first rod 411 may connect the waveguide 330 to the center zone of the window module WM. The second rod 412 may connect the waveguide 330 to the edge zone of the window module WM. The third rod 413 may connect the waveguide 330 to the middle zone of the window module WM. The middle zone may be positioned between the center zone and the edge zone. The middle zone of the window module WM may be formed at a position corresponding to the middle zone of the substrate W. The third rod 413 may heat the middle zone of the substrate W by transferring microwaves to the middle zone of the substrate W. FIG. 11 is a fourth exemplary view illustrating an embodiment of a waveguide constituting a heating device.

The first rods 411, the second rod 412 and the third rod 413 may be provided as the same number of rods. For example, the connecting rod 410 may include one first rod 411, one second rod 412, and one third rod 413, but the present disclosure is not limited thereto. The first rod 411, the second rod 412, and the third rod 413 may be provided to be different from one another in their number. The third rod 413 may be provided as a larger number of rods than the first rod 411. The second rod 412 may be provided as a larger number of rods than the third rod 413.

As described above, the connecting tube may connect the waveguide 330 with the window module WM. The connecting tube may connect the waveguide 330 with the window module WM in the same manner as the connecting rod 410. A detailed description of the connecting tube will be omitted.

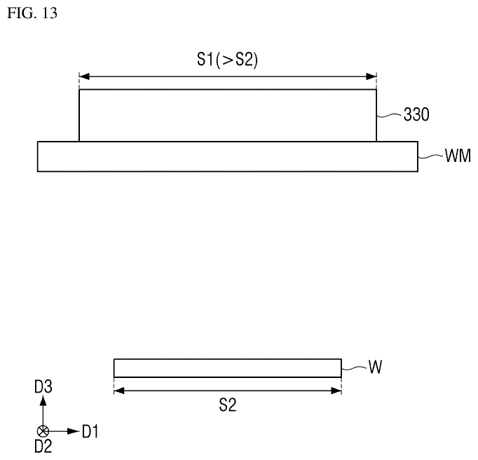

The waveguide 330 may be spaced apart from the upper portion of the window module WM, but may be also in close contact with the upper portion of the window module WM. In this case, the waveguide 330 may be formed at a size and position corresponding to a width S2 of the substrate W. Referring to FIG. 12, a width S1 of the waveguide 330 may be the same as the width S2 of the substrate W, and an end portion of the waveguide 330 may be positioned on the same line in the vertical direction D3 as an end portion of the substrate W, but the present disclosure is not limited thereto. The waveguide 330 may be formed at a size and position wider than the width S2 of the substrate W. Referring to FIG. 13, the width S1 of the waveguide 330 may be wider than the width S2 of the substrate W, and the end portion of the waveguide 330 may be positioned outside the end portion of the substrate W in the horizontal direction D1 or D2. FIG. 12 is a fifth exemplary view illustrating an embodiment of a waveguide constituting a heating device. FIG. 13 is a sixth exemplary view illustrating an embodiment of a waveguide constituting a heating device.

The waveguide 330 may be fully or completely in close contact with the upper portion of the window module WM, but is not limited thereto. The waveguide 330 may be partially in close contact with the upper portion of the window module WM. For example, the waveguide 330 may be in close contact with any one zone of the window module WM, and may not be in close contact with the other zone.

The description will be given by referring back to FIG. 7.

The control module 340 may control the operation of the plurality of microwave generating modules 310a, 310b, 310c, . . . , 310n and the microwave synthesis module 320. The control module 340 may independently control the operation of the plurality of microwave generating modules 310a, 310b, 310c, . . . , 310n. In this case, the control module 340 may be individually connected to each of the microwave generating modules 310a, 310b, 310c, . . . , 310n, but is not limited thereto. The control module 340 may simultaneously control the operation of the plurality of microwave generating modules 310a, 310b, 310c, . . . , 310n. In this case, the control module 340 may be connected to the plurality of microwave generating modules 310a, 310b, 310c, . . . , 310n through one line.

As described above, the plurality of microwave generating modules 310a, 310b, 310c, . . . , 310n may use multi-frequency. The plurality of microwave generating modules 310a, 310b, 310c, . . . , 310n may be provided as multi-frequency sources. When a single frequency is used to heat the substrate W during a process period, a non-uniform electric field distribution may be induced on the surface of the substrate W due to a standing wave effect. In addition, a saturation temperature in the chamber housing CH may become non-uniform.

In order to solve this problem, the control module 340 may generate microwaves by varying a frequency value. Also, the control module 340 may vary a zone heated on the substrate W. When the entire process time is divided into a plurality of time periods, the control module 340 may generate microwaves by varying a frequency value in respective process time units. The control module 340 may heat different zones of the substrate W in respective process time units. The control module 340 may partially heat the substrate W or heat the entire substrate W in respective process time units.

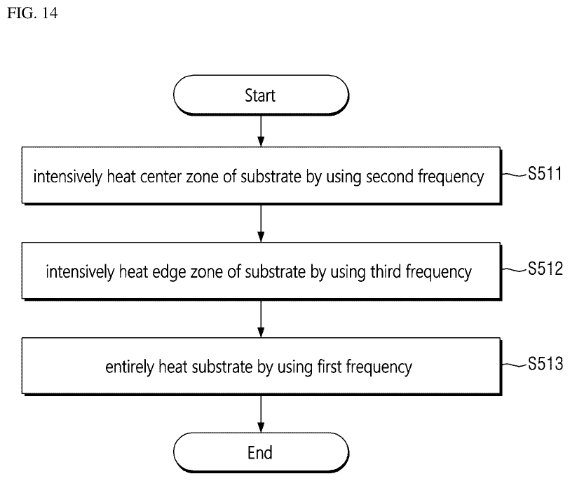

Referring to the example of FIG. 14, the control module 340 may control the operation of the second generating module 310b during a first process time. The second generating module 310b may generate a microwave having a second frequency value. The control module 340 may intensively heat the center zone of the substrate W by using the microwave having a second frequency value (S511).

The control module 340 may control the operation of the third generating module 310c during a second process time subsequent to the first process time. The third generating module 310c may generate a microwave having a third frequency value. The control module 340 may vary the frequency of the microwave from the second frequency value to the third frequency value. The third frequency value may be greater than the second frequency value. The control module 340 may intensively heat the edge zone of the substrate W by using the microwave having the third frequency value (S512).

The control module 340 may control the operation of the first generating module 310a during a third process time subsequent to the second process time. The first generating module 310a may generate a microwave having a first frequency value. The control module 340 may vary the frequency of the microwave from the third frequency value to the first frequency value. The first frequency value may be smaller than the third frequency value. Alternatively, the first frequency value may be smaller than the second frequency value. The control module 340 may entirely heat the substrate W by using the microwave having a first frequency value (S513). FIG. 14 is a flow chart illustrating a substrate heating method when a substrate is treated in accordance with one embodiment.

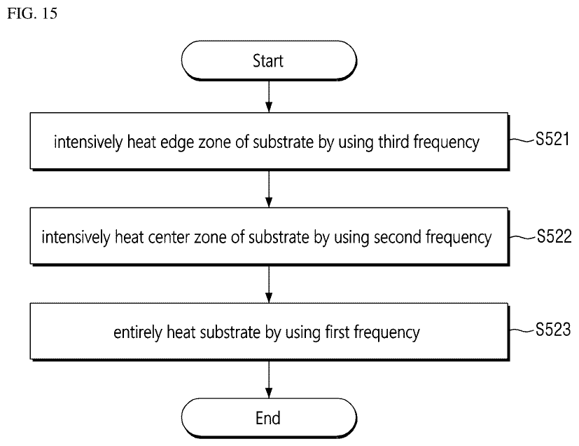

Referring to the example of FIG. 15, the control module 340 may control the operation of the third generating module 310c during the first process time. The third generating module 310c may generate a microwave having a third frequency value. The control module 340 may intensively heat the edge zone of the substrate W by using the microwave having a third frequency value (S521).

The control module 340 may control the operation of the second generating module 310b during the second process time subsequent to the first process time. The second generating module 310b may generate a microwave having a second frequency value. The control module 340 may vary the frequency of the microwave from the third frequency value to the second frequency value. The second frequency value may be smaller than the third frequency value. The control module 340 may intensively heat the center zone of the substrate W by using the microwave having the second frequency value (S522).

The control module 340 may control the operation of the first generating module 310a during the third process time subsequent to the second process time. The first generating module 310a may generate a microwave having a first frequency value. The control module 340 may vary the frequency of the microwave from the second frequency value to the first frequency value. The first frequency value may be smaller than the second frequency value. The control module 340 may heat the entire substrate W by using the microwave having the first frequency value (S523). FIG. 15 is a flow chart illustrating a substrate heating method when a substrate is treated in accordance with another embodiment.

In the present disclosure, while the substrate treating apparatus 200 is treating the substrate W, the heating apparatus 300 may heat the substrate W. The heating apparatus 300 may heat the substrate W by using microwaves. However, in order to check whether the surface temperature of the substrate W is uniformly maintained during the process period, it is necessary to measure the surface temperature of the substrate W continuously.

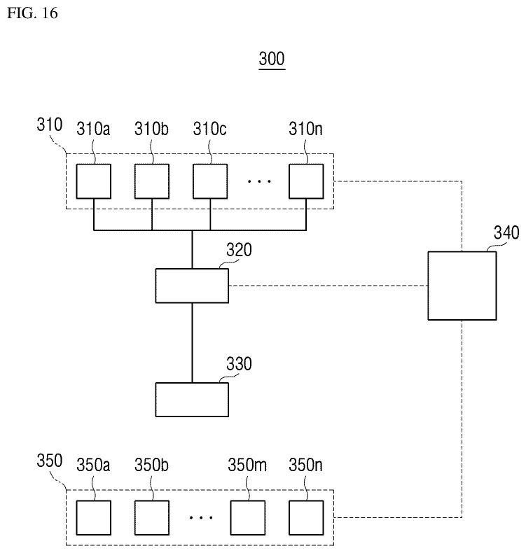

FIG. 16 is a second exemplary view schematically illustrating an internal configuration of a heating device constituting a substrate treating apparatus. Referring to FIG. 16, the heating device 300 may include a microwave generating module 310, a microwave synthesis module 320, a waveguide 330, a temperature measurement module 350, and a control module 340. Hereinafter, a description of redundant portions as compared with the case of FIG. 7 will be omitted, and only portions corresponding to differences therefrom will be described.

The temperature measurement module 350 may measure the surface temperature of the substrate W. The temperature measurement module 350 may measure the surface temperature of the substrate W every predetermined time during the process period. The temperature measurement module 350 may directly measure the surface temperature of the substrate W, and may also indirectly measure the surface temperature of the substrate W. The temperature measurement module 350 may measure a temperature for an upper space of the substrate W inside the chamber housing CH. In this case, the control module 340 may predict the surface temperature of the substrate W based on the measurement result of the temperature measurement module 350. Thus, the temperature measurement module 350 may indirectly measure the surface temperature of the substrate W.

The temperature measurement module 350 may be provided as a plurality of temperature measurement modules. The temperature measurement module 350 may include ‘n’ number of temperature sensors 350a, 350b, . . . , 350m and 350n such as a first temperature sensor 350a, a second temperature sensor 350b, . . . , an (m)th temperature sensor 350m, and an (n)th temperature sensor 350n. The control module 340 may control the heating device 300 based on the measurement result of the plurality of temperature sensors 350a, 350b, . . . , 350m and 350n to selectively heat the substrate W for each zone, thereby uniformly maintaining the surface temperature of the substrate W.

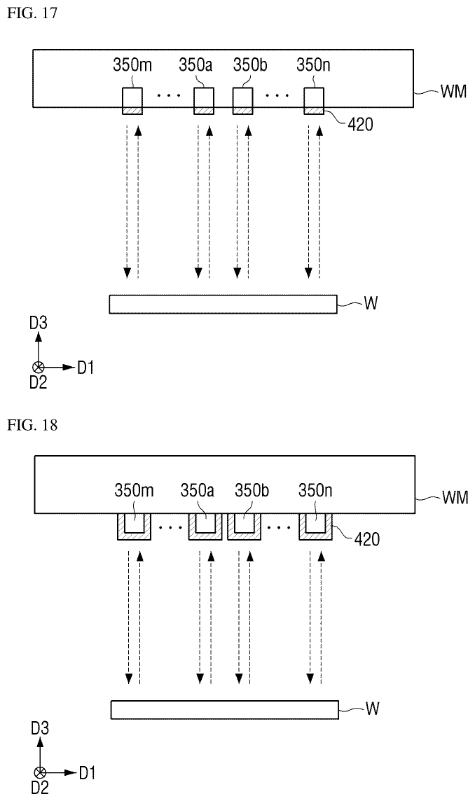

The temperature measurement module 350 may be installed in the window module WM. Referring to FIG. 17, the plurality of temperature sensors 350a, 350b, . . . , 350m and 350n may be installed to be exposed to the bottom of the window module WM. The plurality of temperature sensors 350a, 350b, . . . , 350m and 350n may be in contact with the inner space of the chamber housing CH. The plurality of temperature sensors 350a, 350b, . . . , 350m and 350n may be spaced apart from each other by a predetermined distance.

A coating layer 420 may be formed on a contact surface between each of the temperature sensors 350a, 350b, . . . , 350m and 350n and the inner space of the chamber housing CH. The coating layer 420 may not interfere with each of the temperature sensors 350a, 350b, . . . , 350m and 350n that measure the surface temperature of the substrate W. The coating layer 420 may be formed of an etch-resistant material. The coating layer 420 may prevent each of the temperature sensors 350a, 350b, . . . , 350m and 350n from being damaged by plasma.

The plurality of temperature sensors 350a, 350b, . . . , 350m and 350n may be disposed to be divided for each zone in the window module WM. Some temperature sensors 350a and 350b may be disposed in the center zone of the window module WM. The temperature sensors 350a and 350b disposed in the center zone of the window module WM may measure the surface temperature for the center zone of the substrate W. Some other temperature sensors 350m and 350n may be disposed in the edge zone of the window module WM. The temperature sensors 350m and 350n disposed in the edge zone of the window module WM may measure the surface temperature for the edge zone of the substrate W. The control module 340 may uniformly maintain the surface temperature of the substrate W for each zone by selectively heating the substrate W for each zone based on the measurement result for the center zone of the substrate W and the measurement result for the edge zone of the substrate W. FIG. 17 is a first exemplary view illustrating an embodiment of a temperature measurement module constituting a heating device.

The plurality of temperature sensors 350a, 350b, . . . , 350m and 350n may be disposed to be divided into three or more zones of the window module WM. In this case, the surface temperature of each zone of the substrate W may be measured more finely, and the surface temperature of each zone of the substrate W may be uniformly maintained.

The temperature measurement module 350 may be installed on the upper inner wall of the chamber housing CH. Referring to FIG. 18, the plurality of temperature sensors 350a, 350b, . . . , 350m and 350n may be installed to be attached to the surface of the window module WM positioned in the inner space of the chamber housing CH. In addition, the coating layer 420 may be formed to surround each of the temperature sensors 350a, 350b, . . . , 350m and 350n. FIG. 18 is a second exemplary view illustrating an embodiment of a temperature measurement module constituting a heating device.

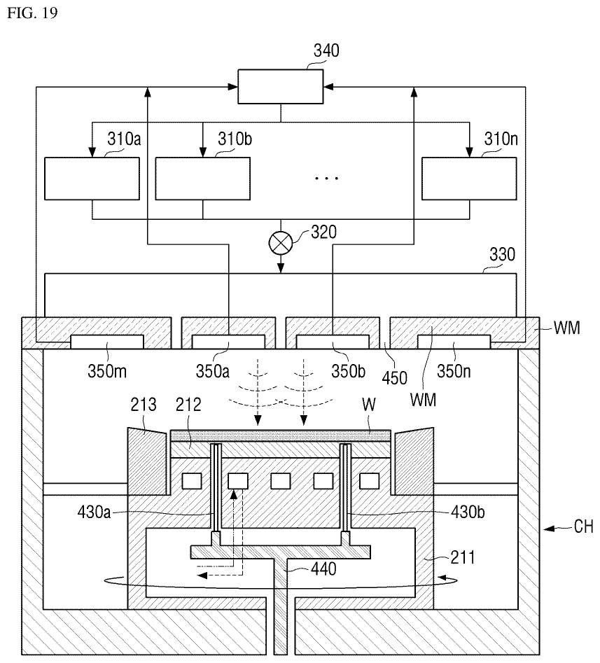

The substrate W may rotate while its treating process is being performed inside the chamber housing CH. Referring to FIG. 19, the substrate W may rotate in accordance with rotation of the substrate support unit 210 that includes a base 211 and an electrostatic chuck 212. Although not shown in FIG. 19, the substrate support unit 210 may be connected to a motor through a rotational shaft. Alternatively, the substrate W may rotate in accordance with rotation of lift pins 430a and 430b for lifting the substrate W. In this case, a lift pin support module 440 may serve as the rotational shaft. The base 211 and the electrostatic chuck 212 may not rotate. The control module 340 may control the operation of the motor to rotate the substrate W.

As described above, the window module WM may be formed of a material capable of passing through microwaves, but is not limited thereto. The window module WM may form a slit 450 on a contact surface with the inner space of the chamber housing CH, and may allow microwaves to pass therethrough through the slit 450. The slit 450 may be in contact with the inner space of the chamber housing CH through the plurality of temperature sensors 350a, 350b, . . . , 350m and 350n. FIG. 19 is an exemplary view illustrating a method of rotating a substrate.

As described above, a small number of second rods 412 may be provided. For example, one second rod 412 may be provided. Alternatively, two second rods 412 may be provided. The small number of second rods 412 may not efficiently transfer microwaves to the entire edge zone of the substrate W. In the present disclosure, the substrate W may be rotated to transfer microwaves to the entire edge zone.

The control module 340 may heat a specific portion of the substrate W for a predetermined time, and then may rotate the substrate W and subsequently heat another portion of the substrate W. For example, the control module 340 may heat the center zone of the substrate W during the first process time, heat the edge zone of the substrate W during the second process time and then rotate the substrate W. The control module 340 may rotate the substrate W by 90°. The control module 340 may heat the remaining portion of the substrate W during the third process time after rotating the substrate W.

The present disclosure relates to a heating device 300 and a substrate treating apparatus 200 including the same. The heating device 300 may heat the surface of the substrate W at a high speed by using a multi-power source or a multi-frequency source, and may uniformly maintain the surface temperature of the substrate W during the process period. The heating device 300 may be provided as a thermal source for an atomic layer etching equipment. The heating device 300 may improve uniformity with respect to a reaction occurring on the surface of the substrate W.

The heating device 300 may control the output of the multi-power source or the multi-frequency source in accordance with a previously set scheduler. The heating device 300 may control the output of the multi-power source or the multi-frequency source in accordance with the result obtained by measuring the surface temperature of the substrate W.

For example, the heating device 300 may use a waveguide operating in a TE01 mode. The heating device 300 may rapidly heat the substrate W with a microwave having a first frequency value at an initial stage. When the substrate reaches a specific temperature, the heating device 300 may heat a predetermined portion of the substrate W with a microwave having a second frequency value. Afterwards, the heating device 300 may rotate the substrate W and heat the remaining portion of the substrate W with a microwave having a third frequency value.

In the present disclosure, detailed heating timing selection and source output selection may be optimized together with process design. Therefore, a high-speed and uniform microwave type heating device may be designed. In addition, various actuating frequencies may be used by overlap at once through a mixer depending on conditions, and may be configured to operate in two or more TE/TM modes depending on a shape of the waveguide.

The heating device 300 may be applied to a thermal atomic layer etching (ALE) system that performs an etching process. The heating device 300 may be applied to a thermal atomic layer deposition (ALD) system that performs a deposition process. The heating device 300 may include a microwave generator having a plurality of output states, and may selectively drive a plurality of microwave generators in accordance with a process design during thermal heating. The heating device 300 may further include an adjustment module for adjusting a position or angle of the substrate W for uniform heating of the substrate W.

Although the embodiments of the present disclosure have been described with reference to the accompanying drawings, it will be apparent to those skilled in the art that the present disclosure can be embodied in other specific forms without departing from the technical concept and characteristics of the present disclosure. Thus, the above-described embodiments are to be considered in all respects as illustrative and not restrictive.

What is claimed is:

1. A substrate treating apparatus comprising:
a chamber housing providing a space in which a substrate is treated;
a substrate support unit supporting the substrate inside the chamber housing;
a showerhead unit providing a process gas into the chamber housing;
a plasma generating unit generating plasma for treating the substrate inside the chamber housing by using the process gas; and
a heating device heating the substrate by using a plurality of electromagnetic waves,
wherein the plurality of electromagnetic waves are different from each other in at least one component of power, frequency or phase.

2. The substrate treating apparatus of claim 1, wherein the electromagnetic wave is a microwave.

3. The substrate treating apparatus of claim 1, wherein the heating device includes:
a plurality of microwave generating modules generating a plurality of microwaves different from each other in at least one component of power, frequency or phase;
a waveguide guiding the plurality of microwaves to an inner space of the chamber housing; and
a control module controlling an operation of each microwave generating module.

4. The substrate treating apparatus of claim 3, wherein the plurality of microwave generating modules generate the plurality of microwaves at different times.

5. The substrate treating apparatus of claim 1, wherein the control module selectively heats the substrate whenever a predetermined time elapses.

6. The substrate treating apparatus of claim 5, wherein the control module sequentially selects different zones of the substrate.

7. The substrate treating apparatus of claim 5, wherein the control module partially heats the substrate and then entirely heats the substrate.

8. The substrate treating apparatus of claim 3, wherein the heating device further includes a microwave synthesis module synthesizing the plurality of microwaves, and the microwave synthesis module operates when the plurality of microwaves are generated simultaneously.

9. The substrate treating apparatus of claim 3, wherein the control module independently controls each microwave generating module.

10. The substrate treating apparatus of claim 3, wherein the heating device includes a plurality of temperature sensors, and further includes a temperature measurement module measuring a surface temperature of each zone of the substrate.

11. The substrate treating apparatus of claim 10, wherein the control module selectively heats the substrate based on the surface temperature of each zone of the substrate.

12. The substrate treating apparatus of claim 1, wherein the substrate is rotated.

13. The substrate treating apparatus of claim 12, wherein the substrate is rotated when partially heated.

14. The substrate treating apparatus of claim 1, further comprising a window module covering an upper portion of the chamber housing,
wherein the heating device is in close contact with the window module or spaced apart from the window module.

15. The substrate treating apparatus of claim 14, wherein the window module is formed of a material that transmits the electromagnetic wave, or a slit through which the electromagnetic wave is transmitted.

16. The substrate treating apparatus of claim 14, wherein the heating device is connected to the window module by using a connecting rod or a connecting tube when spaced apart from the window module.

17. The substrate treating apparatus of claim 16, wherein the connecting rod includes:
a first rod connected to a first portion of the window module, which corresponds to a center zone of the substrate; and
a second rod connected to a second portion of the window module, which corresponds to an edge zone of the substrate.

18. The substrate treating apparatus of claim 17, wherein the second rod is provided as the same number of rods as the first rod or a larger number of rods than the first rod.

19. A heating device comprising:
a plurality of microwave generating modules generating a plurality of microwaves;
a waveguide guiding the plurality of microwaves to a space in which the substrate is treated; and
a control module controlling an operation of each microwave generating module, wherein the substrate is heated using the plurality of microwaves by an apparatus for treating the substrate by using plasma, and
the plurality of microwaves are different from each other in at least one component of power, frequency or phase.

20. A substrate treating apparatus comprising:
a chamber housing providing a space in which a substrate is treated;
a substrate support unit supporting the substrate inside the chamber housing;
a showerhead unit providing a process gas into the chamber housing;
a plasma generating unit generating plasma for treating the substrate inside the chamber housing by using the process gas; and
a heating device heating the substrate by using a plurality of electromagnetic waves,
wherein the heating device includes:
a plurality of microwave generating modules generating the plurality of microwaves;
a waveguide guiding the plurality of microwaves to the space in which the substrate is treated;
a temperature measurement module including a plurality of temperature sensors and measuring a surface temperature of each zone of the substrate; and
a control module controlling an operation of each microwave generating module and each temperature sensor,
wherein the plurality of microwaves are different from each other in at least one component of power, frequency or phase, and
the control module heats the substrate while the substrate is being treated, and selectively heats the substrate based on the surface temperature of each zone of the substrate.
